(19) United States
(12) Patent Application Publication
(10) Pub. No.: US 2026/0117420 A1
(43) Pub. Date: Apr. 30, 2026

(54) MULTIMODAL IMAGING APPARATUS AT ULTRAHIGH PRESSURE

(71) Applicant: The Regents of the University of California, Oakland, CA (US)

(72) Inventors: Prabudhya BHATTACHARYYA, Oakland, CA (US); Norman YAO, Oakland, CA (US); Joel MOORE, Oakland, CA (US); Raymond JEANLOZ, Oakland, CA (US); Satcher HSIEH, Oakland, CA (US); Bryce KOBRIN, Oakland, CA (US); Chong ZU, Oakland, CA (US); Thomas SMART, Oakland, CA (US)

(73) Assignee: The Regents of the University of California, Oakland, CA (US)

(21) Appl. No.: 18/831,775

(22) PCT Filed: Mar. 4, 2024
(86) PCT No.: PCT/US2024/018414

§ 371 Date: Aug. 27, 2025

Related U.S. Application Data
(60) Provisional application No. 63/449,508, filed on Mar. 2, 2023.

(51) Int. Cl. C30B 33/06; G01N 1/28

(52) U.S. Cl. CPC C30B 33/06; G01N 1/286

(57) ABSTRACT

A diamond anvil cell device includes a first diamond anvil having a culet cut to provide a first anvil surface that is substantially perpendicular to a [111] crystal axis thereof; and a second diamond anvil having a culet cut to provide a second anvil surface. The at least one of the first and second diamond anvils includes an ion-crystal-vacancy-defect pair formed therein at a distance of at least 10 nm to 5 μm from the corresponding first or second anvil surface, and a remaining portion of the at least one of the first and second diamond anvils at distances farther than 5 μm from the first or second anvil surface is substantially free of ion-crystal-vacancy-defect pairs. A diamond anvil for a diamond anvil cell is defined by a plurality of flat surfaces resulting from cuts in a bulk piece of diamond having [111], [100] and [110] crystal axes, wherein one of said plurality of flat surfaces is a culet cut to provide an anvil surface of the diamond anvil. The culet is substantially perpendicular to the [111] crystal axis of the bulk piece of diamond. The diamond anvil includes an ion-crystal-vacancy-defect pair formed therein at a distance of at least 10 nm to 5 μm from the anvil surface, and a remaining portion of the diamond anvil at distances farther than 5 μm from the anvil surface is substantially free of ion-crystal-vacancy-defect pairs.

### CROSS-REFERENCE OF RELATED APPLICATION

This application claims priority to U.S. Provisional Application No. 63/449,508 filed Mar. 2, 2023; the entire contents of which are hereby incorporated by reference.

### FEDERAL FUNDING

This invention was made with government support under grant number DE-AC02-05-CH11231 awarded by the Department of Energy. The government has certain rights in the invention.

### BACKGROUND

### 1. Technical Field

The currently claimed embodiments of the present invention relate to ultrahigh pressure methods, devices, and systems.

### 2. Discussion of Related Art

Diamond anvil cells (DACs) are standard tools for use in high-pressure physics. These applications are relevant to geophysics, material science, condensed matter physics, etc. The basic design of a DAC comprises two anvil-shaped diamonds fixed to a cell body. A gasket sandwiched between the anvils provides the high-pressure chamber.

Around 1949, researchers at the University of Chicago started to realize the usefulness of using diamonds in high pressure research. Almost a decade later, in 1958, Charles Weir at the National Bureau of Standards (NBS) made the first diamond anvil cell. Interestingly, researchers at NBS had access to confiscated contraband jewelry diamonds that (coincidentally) were ideal for high pressure work. However, during this period, the idea of leveraging the transparency of diamonds to directly look at the sample eluded researchers. Alvin Van Valkenburg is credited to have serendipitously discovered this fact in 1958, thereby birthing our current idea of a diamond anvil cell. Looking through his diamond anvil loading to check for alignment, Valkenburg directly observed phase separation of his high-pressure sample. To study materials under quasi-hydrostatic pressure, Valkenburg is also credited to have pioneered the gasket technique that is now routinely used in practically all high-pressure loadings.

In geophysics, where one is interested in phases of matter in planetary interiors, high pressure is often quoted in gigapascals (GPa), with 1 GPa=10.000 atm and the pressure at the center of the Earth being ˜360 GPa. The earliest explorations in DACs were able to achieve a few GPa of pressure (an enormous feat at the time) [12]. Nevertheless, one of the clear directions in high pressure research was making this journey to the Earth's center (on the pressure scale). The impressive push to megabar (Mbar) pressures (1 Mbar=100 GPa), along with conclusive calibration techniques, was developed by Dave Mao and Peter Bell [12, 70]. Even before this, however, many ideas were already put forth to explore the colorful world of high-pressure phases. In particular, in 1968, Neil Ashcroft proposed the possibility of high temperature superconductivity in a high-pressure metallic phase of Hydrogen [6].

Metallic Hydrogen became a unicorn of sorts, driving researchers to achieve higher and higher pressures on one hand and adding fuel to the search for high temperature superconductors on the other [13]. This decades-long effort was reignited with recent breakthroughs in superhydride materials [32, 33, 95]. The starting point of our project to explore NV sensing under pressure coincided with the discovery of high temperature superconductivity in H₃S above 100 GPa pressures by Mikhail Eremets' team [32]. Our initial motivation to push NV sensing to megabar pressures was fueled by all the interest and activity in high-pressure hydrides with the dream of imaging the Meissner effect in these systems.

In discovering DACs, Valkenburg's key breakthrough was the realization that he could do meaningful science simply by looking through the diamond and mapping the high pressure chamber. In some sense, the NV center empowers us to continue on this path by opening a new window to directly image the magnetic and stress fields in the anvil.

The basic idea of a diamond anvil cell is very intuitive. Two opposing gem-cut diamonds with flat culets are pressed together to create a high-pressure region. The sample, enclosed at the center of a metal gasket, is sandwiched between the culet faces of the diamond. In our experiments, the gasket was fashioned out of rhenium foil by pre-indenting up to 25-30 GPa and subsequently drilling a hole in the center of the indent.

However, the conventional DACs are limited in pressures that can be achieved. There thus remains a need for improved DACs that can be used for even higher-pressure measurements.

### SUMMARY

A diamond anvil cell device according to an embodiment of the current invention includes a first diamond anvil having a culet cut to provide a first anvil surface that is substantially perpendicular to a crystal axis thereof; and a second diamond anvil having a culet cut to provide a second anvil surface. The at least one of the first and second diamond anvils includes an ion-crystal-vacancy-defect pair formed therein at a distance of at least 10 nm to 5 μm from the corresponding first or second anvil surface, and a remaining portion of the at least one of the first and second diamond anvils at distances farther than 5 μm from the first or second anvil surface is substantially free of ion-crystal-vacancy-defect pairs.

A diamond anvil for a diamond anvil cell according to an embodiment of the current invention is defined by a plurality of flat surfaces resulting from cuts in a bulk piece of diamond having [111], [100] and [110] crystal axes, wherein one of said plurality of flat surfaces is a culet cut to provide an anvil surface of the diamond anvil. The culet is substantially perpendicular to the [111] crystal axis of the bulk piece of diamond. The diamond anvil includes an ion-crystal-vacancy-defect pair formed therein at a distance of at least 10 nm to 5 μm from the anvil surface, and a remaining portion of the diamond anvil at distances farther than 5 μm from the anvil surface is substantially free of ion-crystal-vacancy-defect pairs.

A method of producing a diamond anvil for a diamond anvil cell according to an embodiment of the current invention includes providing a piece of uncut diamond having [111], [100] and [110] crystal axes; cutting the diamond to provide a plurality of flat surfaces, one of the plurality of flat surfaces being a culet cut to provide an anvil surface of the diamond anvil, wherein the culet is substantially perpendicular to the crystal axis; and implanting an ion in the diamond anvil to form an ion-crystal-vacancy-defect pair formed therein at a distance of at least 10 nm to 5 μm from the anvil surface. A remaining portion of the diamond anvil at distances farther than 5 μm from the anvil surface is substantially free of ion-crystal-vacancy-defect pairs.

### BRIEF DESCRIPTION OF THE DRAWINGS

FIGS. 1A-1C provide a schematic illustration of a diamond anvil (FIG. 1A) and a diamond anvil cell design (FIGS. 1B-1C);

FIGS. 2A-2D show four examples of conventional diamond anvil cell designs;

FIGS. 3A-3B show some examples of types of culets;

FIGS. 4A-4C are schematic illustrations showing different crystal cuts of the diamond culet;

FIG. 5A is a schematic illustration of a diamond anvil cell device 100 according to an embodiment of the current invention; FIG. 5B shows an example of the diamond anvil cell of FIG. 5A;

FIGS. 6A-6B show data contrasting an embodiment of the current invention to conventional devices;

FIG. 7 provides data for magnetic splitting according to an embodiment of the current invention;

FIG. 8 provides additional data according to an embodiment of the current invention;

FIG. 9A provides data for C\continuous wave ODMR with ˜4% contrast and Rabi oscillations (FIG. 9B) at 120 GPa according to an embodiment of the current invention;

FIG. 10A is a schematic illustration of an assembly of wire for microwave delivery according to an embodiment of the current invention along with an example in FIG. 10B of spin echo measurement at ˜140 GPa with inset showing Rabi measurement.;

FIG. 11A is a schematic illustration of an NV center and FIG. 11B shows an example of corresponding fluorescence;

FIGS. 12A-12C show an example of NV orbitals and level structure;

FIGS. 13A, 13B describe the NV ground state spin corresponding to FIGS. 12A-12C;

FIG. 14 illustrates the NV ISC mechanism;

FIG. 15 is a schematic illustration of a confocal NV fluorescence microscope;

FIG. 16 shows a schematic of the MW circuit used in our experiments according to an embodiment of the current invention;

FIG. 17 provides NV measurements according to an embodiment of the current invention; and

FIG. 18 shows an example of vector magnetometry.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

### Diamond Anvil Cells

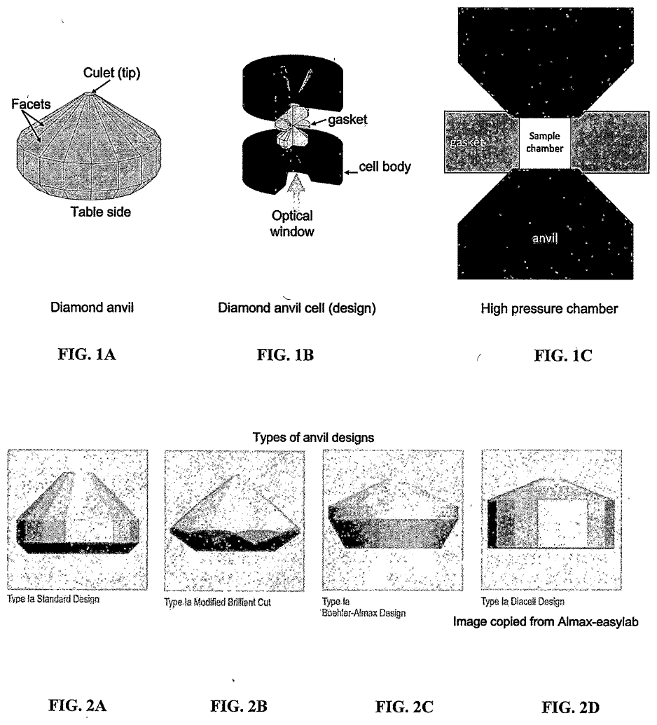

As we noted above, diamond anvil cells (DACs) are standard tools for high-pressure physics. These applications are relevant to geophysics, material science, condensed matter physics, etc. The basic design of a DAC comprises two anvil-shaped diamonds fixed to a cell body. A gasket sandwiched between the anvils provides the high-pressure chamber. The standard design of the DAC has been used for decades and can be customized to the specific purpose of the experiment. FIGS. 1A-1C provide a schematic illustration of a diamond anvil (FIG. 1A) and a diamond anvil cell design (FIGS. 1B-1C).

There are many variations of DAC design (Symmetric DAC, Plate DAC, Panoramic DAC) and many choices for use of materials in making a cell body (Beryllium copper, Steel, NiCrAl, Tungsten Carbide, Inconel, Pascalloy etc.) Additionally, there are many choices for materials that can be used as gaskets (Rhenium, Berrylium copper, Steel, Tungsten Carbide, insulating gaskets, cubic boron nitride, Kapton etc.) and backing plates (steel, Tungsten Carbide, Berrylium copper, cubic boron nitride).

There are many existing anvil designs (Standard cut, Brilliant cut, Boehler-Almax cut). FIGS. 2A-2D show four examples of conventional diamond anvil cell designs.

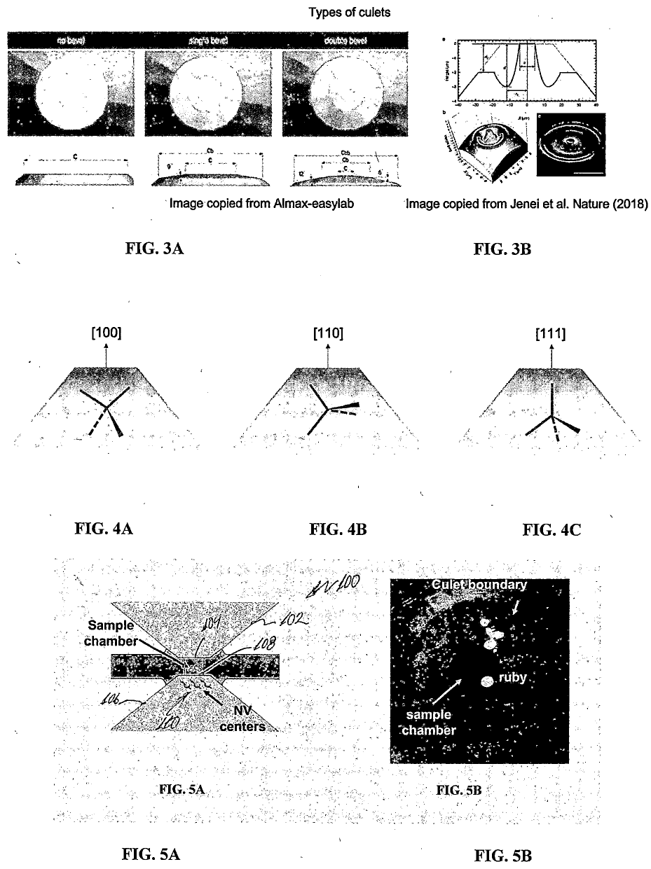

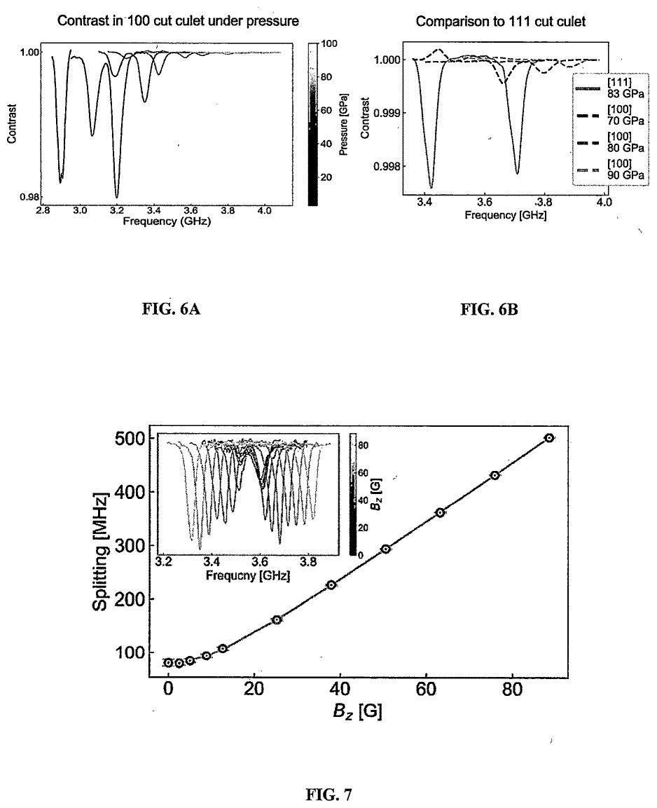

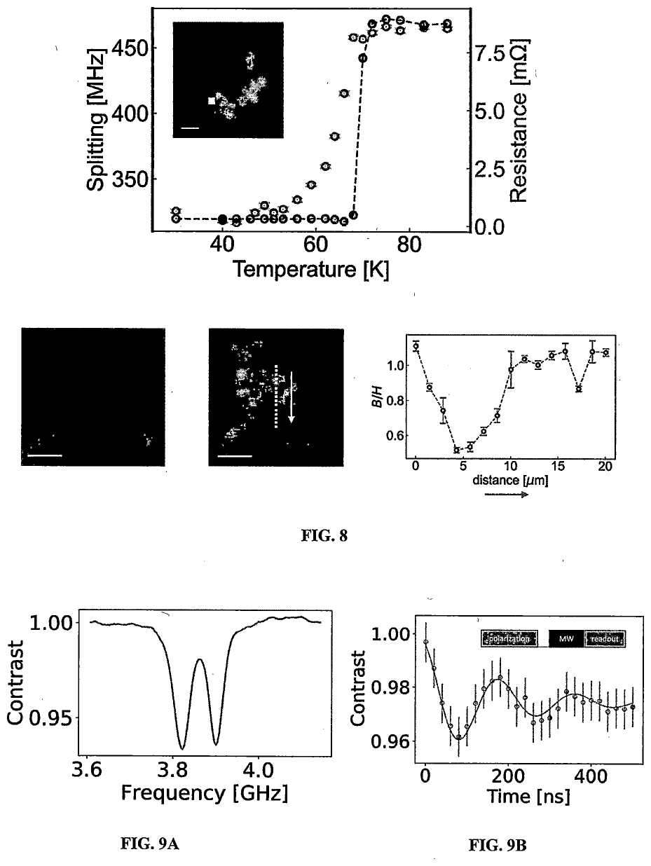

For each design, there are many options for culet cuts (flat culets, single bevel culet, double bevel culets, customized FIB culets). FIGS. 3A-3B show some examples of types of culets.

Additionally, the diamond anvil can be polished out of different diamond types (Type Ia, Type Ib, Type IIac, Type Iias etc). Classification of diamond types pertains to the concentration of different kinds of crystal defects in diamond. Finally, the culet of the diamond anvil may be of a specific crystal cut. The crystal cut of the culet specifies the orientation of the culet face with respect to the diamond crystal. 100-cut and 110-cut culets are commonly used in high pressure work.

FIGS. 4A-4C are schematic illustrations showing different crystal cuts of the diamond culet. The crystal bonds of the diamond are oriented differently for different crystal cuts.

There are a range of measurements that can be performed on the sample under high pressure (transport, spectroscopy, susceptibility measurements etc.). Some embodiments of the current invention are directed to a specific kind of measurement using color centers in the diamond anvil. In addition, we show the usefulness of 111-cut culets (up to a miscut of ˜10 deg.) for devices and methods of measurement under high pressure according to some embodiments of the current invention.

FIG. 5A is a schematic illustration of a diamond anvil cell device 100 according to an embodiment of the current invention. FIG. 5B shows an example of the diamond anvil cell of FIG. 5A. The diamond anvil cell device 100 includes a first diamond anvil 102 having a culet cut to provide a first anvil surface 104 that is substantially perpendicular to a [111] crystal axis thereof, and a second diamond anvil 106 having a culet cut to provide a second anvil surface 108. FIG. 4C is a schematic illustration showing an example of a culet cut to provide a first anvil surface 104 that is substantially perpendicular to a [111] crystal axis thereof. In some embodiments, alternatively, or additionally, the culet cut to provide the second anvil surface 108 can be substantially perpendicular to a [111] crystal axis thereof.

At least one of the first and second diamond anvils 102, 106 includes an ion-crystal-vacancy-defect pair 110 formed therein at a distance of at least 10 nm to 5 μm from the corresponding first or second anvil surface, and a remaining portion of the at least one of the first and second diamond anvils 102, 106 at distances farther than 5 μm from the first 104 or second 108 anvil surface is substantially free of ion-crystal-vacancy-defect pairs. In FIG. 5A, three Nitrogen Vacancy (NV) pairs are illustrated schematically as an example of at least one ion-crystal-vacancy-defect pair. However, the general concepts of the current invention are not limited to any specific number of ion-crystal-vacancy-defect pairs and are not limited to specific types of ion-crystal-vacancy-defect pairs.

The diamond anvil 100 according to some embodiments can further include a plurality of implanted ion-crystal-vacancy-defect pairs within the at least one of the first and second diamond anvils 102, 106 at distances of 10 nm to 5 μm from the corresponding first or second anvil surface (104 and/or 108) at a density of 1 part per billion to 50 parts per million. In some embodiments the density is 1 part per million to 10 parts per million. In some embodiments, an ion-crystal-vacancy-defect pair includes an ion selected from the group consisting of germanium, nitrogen, silicon, and tin. In some embodiments, each of the ion-crystal-vacancy-defect pairs includes an ion selected from the group consisting of germanium, nitrogen, silicon, and tin. In some embodiments, the ion-crystal-vacancy-defect pair includes a nitrogen ion. In some embodiments, each of the ion-crystal-vacancy-defect pairs includes a nitrogen ion.

### Color Centers in Diamonds

Color centers are fluorescent crystal defects in diamond. There are several techniques for incorporation of color centers in diamond crystals. For the Nitrogen Vacancy center (a specific type of color center), some recipes are provided below:
1. In Type Ib, Type IIac, and Type IIas diamonds, one can perform ion implantation (using commercial/custom focused ion beam or other techniques) followed by annealing to created color centers. This technique can create color centers between 10 nm→1 um below the surface of the culet.
   a. Implantation energies may range from 12-500 keV with dosage up to 10¹⁵ ions/cm².
   b. Annealing conditions may include temperatures from 700 C-1300 C under vacuum (<10⁻⁶ mbar) or in a gaseous environment (such as O², Ar etc.).
2. Laser annealing by focusing high power lasers (for example around 10 W or higher) on the diamond surface.

A technique to work with the NV center comprises fluorescence microscopy in either confocal or widefield configuration where laser light (for example at 532 nm, or more generally between 400 nm-600 nm) is used to illuminate the sample and fluorescence from the sample (between 637 nm-900 nm) is measured using a photodiode, single photon counting module, or a CCD/EMCCD camera.

The NV color center is a spin-1 electronic system. The fluorescence of the system and the spin are intimately connected and allow us to perform Optically Detected Magnetic Resonance (ODMR) measurements, wherein optical excitation can be used to prepare the system in a specific spin state and the fluorescence contrast can be used to measure spin state of the system. One can also apply microwaves to coherently control the spin state of the system.

In some embodiments, the diamond anvil cell device 100 can include a first cell body attached to said first diamond anvil 102; a second cell body attached to the second diamond anvil 106; and a gasket defining a hole therethrough and arranged between the first and second diamond anvils 102, 106 so as to form the pressure chamber. (See FIG. 1B for an example.) Note that the cell body can be a composite structure in some embodiments. In some embodiments. The first and second cell bodies are each formed from at least one of Beryllium copper, Steel, NiCrAl, Tungsten Carbide, Pascalloy, Vascomax, Inconel, cubic boron nitride; and the gasket is formed from at least one of Rhenium, Berrylium copper, Steel, cubic boron nitride, Kapton, and Tungsten Carbide.

There are two standard measurement protocols. In a continuous wave measurement, excitation light is always ON and the fluorescence is collected while microwaves are applied to the system. As the microwave frequency is swept across a spin resonance a change in the measured fluorescence occurs. In a pulsed measurement, the system is first prepared in a specific spin state (using a combination of optical and microwave pulses). Following this, a set of predetermined microwave pulsed are used to perform a measurement. After this the fluorescence of the system is collected to measure the final state of the NV center. Pulsed measurements encompass an array of different measurements each catering to specific goals.

In our previous work/patent application, we demonstrated the use of color centers in diamond for sensing under high pressure in diamond anvil cells. (See PCT/US2019/067503, filed Dec. 19, 2019 and assigned to the same assignee as the current application, the entire contents of which are incorporated herein by reference.) According to some embodiments of the current application, we extend the use of this technique to higher pressures than before and improve the measurement signal to noise by applying stronger microwave radiation for spin manipulation.

### Applications

### Measurements Using Defect Centers in Diamond Anvils of 111 Crystal Cut

In continuous wave ODMR, signal contrast is the difference between the fluorescence on resonance to the fluorescence off resonance (the latter is typically normalized to 1). The ODMR contrast of NV centers typically degrades with increasing pressure. This is because the application of pressure induces crystal stress in the diamond anvil which affects the photo physics of color centers.

We demonstrate that the use of color centers in 111 cut culets showing superior measurement contrast at high pressures. This technique can be used in diamond anvils of different designs (standard, brilliant, Boehler-Almax etc.) and different culet geometries (flat/bevelled/double bevelled etc). Furthermore, this application is compatible with any type of Diamond anvil cell (plate, panoramic, symmetric; etc.) used for the measurement. We demonstrate measurements using 111 cut culets up to pressures of 140 GPa but we believe this technique can be extended even higher pressures.

The application of magnetic fields can induce splitting between the spin states (Zeeman effect) that can be further measured in continuous wave ODMR.

We demonstrate the use this technique for spatially resolved magnetometry on high pressure superconductors.

### Improvement In MW Delivery for Conducting Continuous Wave and Pulsed Measurements

The signal to noise ratio of both continuous wave and pulsed measurements depends greatly on the amplitude (equivalently, power) of the microwave field applied to the NV center. In our previous patent application cited above, we use a wire cut out of platinum or gold foil to apply microwaves to the sample. In this example according to an embodiment of the current invention, we improve our technique to get stronger microwave delivery and demonstrate continuous wave ODMR with >1% contrast and pulsed measurements (rabi oscillations and spin echo) at 140 GPa pressures.

FIG. 9A shows continuous wave ODMR with ˜4% contrast and FIG. 9B shows Rabi oscillations at 120 GPa.

The circuit for delivering microwaves (MW) comprises a MW source that is amplified using a MW amplifier. The amplified microwaves are directed to the sample by a coax connector. At the cell, the center pin of the coax connector is soldered/connected to a copper wire which is directly soldered/connected to the Pt/Au wire that delivers MW to the NV centers in the culet. The other end of the Pt/Au wire is connected to a separate copper wire. This second copper wire is connected to a coax cable that is attenuated and subsequently terminated using a 50 ohm terminator.

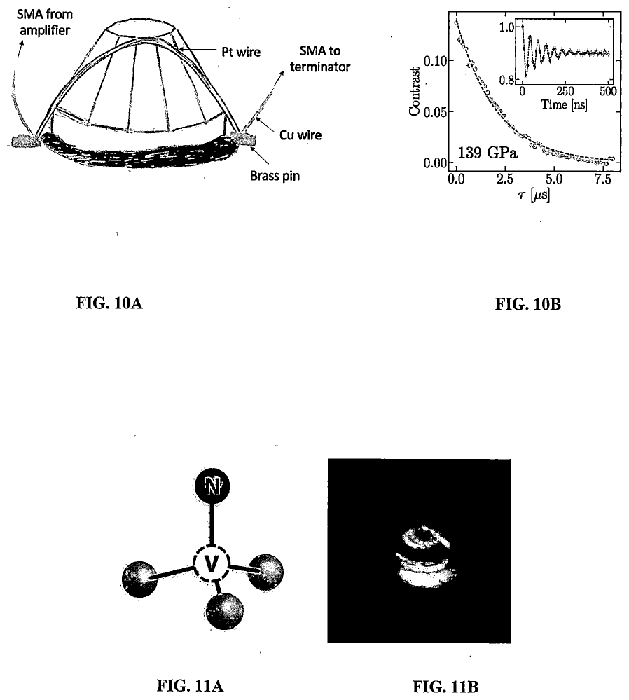

FIG. 10A is a schematic illustration of an assembly of wire for microwave delivery in Diamond anvil cells according to an embodiment of the current invention. FIG. 10B provides spin echo measurement at ˜140 GPa with inset showing Rabi measurement.

The phrase “substantially perpendicular to said [111] crystal axis” as used herein means that it is within ±10 degrees tolerance.

The phrase “substantially free of ion-crystal-vacancy-defect pairs” as used herein means that the number, or density, is sufficiently low to obtain the desired signal-to-noise ratio.

### Further Background and Examples

The following describes further embodiments and examples of the current invention. The general concepts of the current invention are not limited to these examples.

### The NV Center in Diamond

There is no dearth of papers, reviews, and theses detailing the various facets of this topic [29, 73, 9]. Rather than being exhaustive. There is much excitement about “quantum technologies” spanning a wide gamut of platforms in atomic and condensed matter physics. The overarching goal is to leverage the quantum properties of these systems (such as coherence, superposition, or entanglement) to outperform classical techniques in measurement and computation. While there is no silver bullet (yet), each platform has the scope and particular strengths catered toward specific tasks.

The NV center is one such emerging platform with promising prospects as a robust and versatile quantum sensor. NV sensing is a burgeoning field encompassing a vast array of work. In this section, we focus on the application of NV sensing at high pressures [70].

The diamond crystal is a lattice of tetrahedrally bonded carbon atoms [82]. The nitrogen vacancy color center is a point defect in diamond comprising a substitutional nitrogen atom adjacent to a vacant lattice site. The following sections illustrate some of the unique properties of the NV center that render it particularly useful among the numerous defects that can (and invariably do) occur in natural as well as lab-grown diamonds.

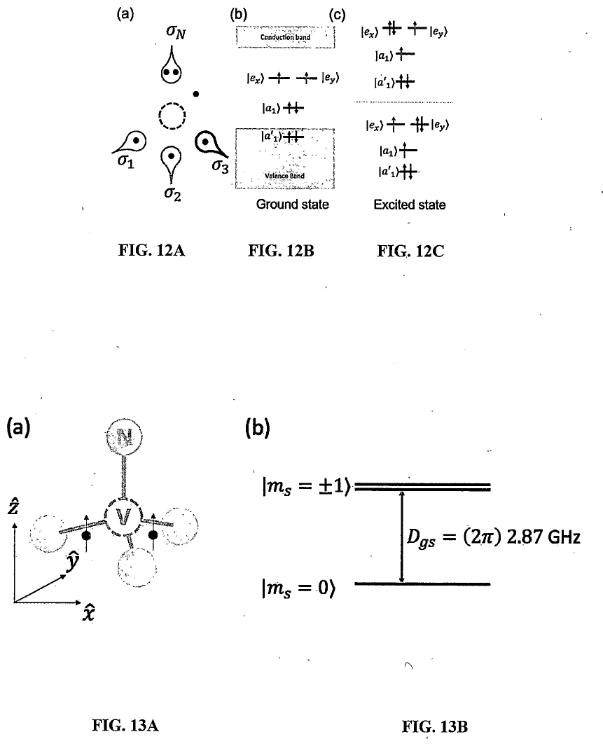

FIG. 11A is a ball and stick diagram of an NV center. The repeating tetrahedra of carbon atoms (grey) form the diamond lattice. The NV center comprises a substitutional nitrogen atom (blue) adjacent to a vacant lattice site (shown with a broken line). FIG. 11B shows one of the defining properties of the NV center, its fluorescence. A diamond rich in NV centers glows bright red, as the sample shown in this picture.

### Synthesis

There are several techniques for synthesizing NV centers catering to the specifics of the application in mind. The following parameters can help determine the appropriate diamond sample and synthesis recipe:
Required concentration of NV centers
Depth of NV centers from the diamond surface
Presence of other magnetic or charge defects (such as ¹³C and substitutional nitrogen defects)

The experiments in this section are with high-pressure high-temperature (HPHT) synthesized Type Ib diamond procured directly from the vendor (Almax Easylab or SYNTEK Corp). Type Ib diamond is concentrated with single substitutional nitrogen defects (& 10 ppm of P1 centers) [108] and is pale yellow in color. For our applications, we required a high concentration of NV centers near the surface. To achieve this, we used SRIM [112] to simulate the necessary energy and dosage of implanted (¹²C⁺) ions to create ˜10 ppm concentration of vacancies up to 50 nm beneath the surface. Our implantation recipe was the following:

$$A dosage of 2.25 \times {10}^{11} ions / {cm}^{2} at energies near 12 keV$$

$$A dosage of 6.75 \times {10}^{11} ions / {cm}^{2} at energies near 30 keV$$

The final synthesis step was to anneal the sample at temperatures above 850° C. in high vacuum (<10⁻⁶ mbar). At these temperatures, the vacancies become mobile in the lattice and may migrate to sites adjacent to naturally occurring P1 centers. Although stochastic, the formation of NV centers in this manner is energetically favorable and impedes further migration of vacancies. Anecdotally, the overall conversion efficiency of P1 centers is ≈10% yielding a concentration of ≈1 ppm of NV centers in our samples.

### Physics of the NV Center

One of the defining properties of the NV center is its fluorescence. A diamond enriched with NV centers is pink in color and, when illuminated, has a beautiful bright red glow (FIG. 11B). In practice, experiments harvest these fluorescent photons to measure the spin state of the NV center. Therefore, it is imperative to understand the level structure of the NV center and its associated dynamics if one is to employ it as a sensor. The physics of the NV center is (for the most part) the physics of the electrons that it hosts. Consequently, we can get a good understanding of its properties by considering the quantum mechanics of the orbital and spin degrees of freedom of the NV electrons.

### Level Structure of the NV Electrons

Pure diamond with no defects has a bandgap of 5.5 eV (corresponding to deep UV wave-lengths of 225 nm) [29]. Generically, defect centers in such high band gap materials can have localized orbitals whose energies lie within the gap. Color centers are a class of such defects that can fluoresce owing to electronic transitions between these orbitals. By virtue of their fluorescence, such color centers paint a transparent diamond in their unique hues.

In the case of the NV center, these localized orbitals can be constructed from the atomic orbitals of the constituent Nitrogen and Carbon atoms. These atomic orbitals are denoted as ON for the Nitrogen orbital and σᵢ (i=1, 2, 3) for the three dangling bonds of the lattice Carbon atoms (FIG. 12A). The NV center is symmetric under operations of the C_{3V} point group. This group is generated by a 120° rotation around the NV axis and a reflection across the plane formed by the NV axis and a Carbon dangling bond. The irreducible representations of the C_{3V} group dictate how these four atomic orbitals mix with each other to render the molecular orbitals of the NV center [29]. These localized molecular orbitals of the defect center can be written as follows:

$$\vert {a}_{1} 〉 = α \vert {σ}_{N} 〉 + \frac{β}{\sqrt{3}} ( \vert {σ}_{1} 〉 + \vert {σ}_{2} 〉 + \vert {σ}_{3} 〉 ) \qquad ( 1.1 )$$

$$\vert {a}_{1}^{′} 〉 = \frac{α}{\sqrt{3}} ( \vert {σ}_{1} 〉 + \vert {σ}_{2} 〉 + \vert {σ}_{3} 〉 ) + β \vert {σ}_{N} 〉 \qquad ( 1.2 )$$

$$\vert {e}_{x} 〉 = \frac{1}{\sqrt{6}} ( 2 \vert {σ}_{1} 〉 - \vert {σ}_{2} 〉 - \vert {σ}_{3} 〉 ) \qquad ( 1.3 )$$

$$\vert {e}_{y} 〉 = \frac{1}{\sqrt{2}} ( \vert {σ}_{2} 〉 - \vert {σ}_{3} 〉 ) \qquad ( 1.4 )$$

In essence, |a₁ [symbol] and |a′₁ [symbol] orbitals are symmetric under all C_{3V} operations and correspond to the one-dimensional (trivial) representation of this group. In contrast, the degenerate |eₓ [symbol] and |e_{y} [symbol] orbitals correspond to the two-dimensional irreducible representation of the C_{3V} group [73].

FIGS. 12A-12C describe an example of NV orbitals and level structure: (a) A diagram of the NV center showing the Nitrogen orbital σ_{N} with an electron lone pair (black dots) and the dangling bonds of the Carbon atoms σᵢ with one electron each. The NV orbitals are built out of linear combinations of the four atomic orbitals and populated by a total of six electrons for the NV center. The additional electron gained from the lattice is shown near the vacant site. (b) In the ground state of the NV, the degenerate |eₓ [symbol] and |e_{y} [symbol] orbitals are each populated by one electron. Together they form an orbital singlet spin triplet state to minimize the coulomb interaction energy of the two electrons. Therefore, the ground state of the NV center is spin 1. The energies of the NV orbitals relative to the band structure of the diamond are shown [29]. (c) In the electronic excited state of the NV center, an electron may be promoted from the |a₁i orbital to either of the |e_{x,y} [symbol] orbitals. As a result, there are six possible states in this manifold (³E).

The energies of these orbitals can be determined by ab initio simulations considering kinetic energies of the orbital wavefunctions as well as electrostatic energies between the electrons and the nitrogen and carbon nuclei. For practical purposes, it is sufficient to think about the (|eₓ [symbol] , |e_{y} [symbol] , |a₁ [symbol] ) orbital degrees of freedom since the |a′₁ [symbol] state is believed to lie in the valence band of diamond [29].

### The NV Ground State

Knowing the energies of the orbitals, we understand the electronic structure of the ground state. We have two electrons from the Nitrogen lone pair and one each from the Carbon dangling bonds, making a total of five electrons. At this point, it is important to note that the NV center can exist in one of two charge states:
the neutral NV⁰ charge state with 5 electrons
the negatively charged NV-state with 6 electrons (the extra electron coming from a charge donor in the lattice)

Practically all applications of the NV centers deal with the negatively charged NV⁻ center as shown in FIG. 12A. Populating the NV orbitals according to the pairing rules, we can construct the electronic configuration of the NV ground state (see FIG. 12B). The |a′₁ [symbol] and |a₁ [symbol] orbitals are fully occupied, and there are two unpaired electrons in the degenerate |eₓ [symbol] and |e_{y} [symbol] states. Considering the orbital and spin degrees of freedom, we can construct the following candidate antisymmetric states for the NV electrons:

$$\vert orbital singlet 〉 ⊗ \vert spin triplet 〉$$

$$\vert orbital triplet 〉 ⊗ \vert spin singlet 〉$$

The energies of the six states are determined by the coulomb interaction and the spin-spin dipole interaction between the two electrons. Knowing that the coulomb interaction is stronger, we can infer that the orbital singlet (|eₓ e_{y} [symbol] −|e_{y} eₓ [symbol] ) state, with lower spatial overlap, will have lower energy than the orbital triplet state. Therefore, the electronic ground state of the NV center is an orbital singlet and spin triplet (S=1) state:

$${}^{3} {A}_{2} = ( \vert {e}_{x} {e}_{y} 〉 - \vert {e}_{y} {e}_{x} 〉 ) ⊗ \vert S = 1 , {m}_{s} 〉 \qquad ( 1.5 )$$

This state is called A₂ because of its transformation properties under C_{3V} operations.

The energies of the triplet sublevels are determined by the spin-spin dipole interaction between the two electrons. Here too, we can make a heuristic argument to know the relative energies of the three states. First, note that the N-V axis is the quantization axis of the spins (essentially, S_{z} of the electrons will be either “up” or “down” along the NV axis) (FIG. 13A). Second, the |eₓ [symbol] and |e_{y} [symbol] orbitals comprise the Carbon dangling bonds, so the electrons will be dispersed along the XY plane of the defect. In this configuration, one can imagine that having the two electron spins align (both pointing “up” or “down” along the NV axis) will have higher interaction energies than having them anti-aligned. Therefore, the |mₛ=0 [symbol] state will be lower in energy than the |mₛ=±1 [symbol] states. In practice, we model the |mₛ=±1 [symbol] states as degenerate and separated by the |mₛ=0 [symbol] state by 2.87 GHz (FIG. 13B).

FIGS. 13A and 13B illustrate NV ground state spin: (a) The coordinate system associated with the NV center showing the quantization axis of the electronic spin. The NV center is symmetric with respect to 120° rotations around the \hat{z} axis, and the reflections across planed formed by the Nitrogen-Vacancy-Carbon lattice points. The ground state |eₓ [symbol] and |e_{y} [symbol] orbitals are linear combinations of the Carbon dangling bonds. Therefore, the ground state electronic configuration is dominantly distributed across the planar region formed by the carbon orbitals with their spin oriented along the \hat{z} axis. As a consequence, when the spins are aligned (|mₛ=±1 [symbol] states), their dipole-dipole interaction energy is higher than when they are antialigned. (b) The ground state spin sublevels are split by D_{gs}≈(2π)×2.87 GHz with the |mₛ=±1 [symbol] states being degenerate to each other. Given that D_{gs} corresponds to a temperature of 140 mK, the ground state spins are fully mixed at room temperature with ⅓ of the population in each spin state. The ground state Hamiltonian is H=D_{gs}S_{z}² where D_{gs} is called the zero-field splitting.

Note: Use of lower case (\hat{x}, ŷ, \hat{z}) to refer to the reference frame of the NV center and upper case (\hat{X}, Ŷ, \hat{Z}) to refer to the lab frame. This will be important in the discussion of stress sensing and vector magnetometry. In some cases, the two reference frames are coincident, but this may not be true in general.

### Why the NV⁻ Center?

As mentioned earlier, almost all applications of the NV center involve the negatively charged NV-center. The superior spin coherence properties of the NV⁻ center stem from an effective decoupling of the spin and orbital degrees of freedom. Consider spin-orbit couplings of the form L_{±}S_{∓} that act on the system. The ground state of the NV⁰ center is an orbital doublet (|e_{x,y} [symbol] ) with spin ½. Since the orbital states are subject to phonon-mediated decoherence [52], any spin-orbit coupling can have parasitic effects on the spin coherence of the system. In contrast, the ground state of the NV-center, being an orbital singlet, is unaffected by such spin-orbit coupling terms. This isolates the NV-spin from phonon-induced decoherence mechanisms. Throughout this section, the NV center will exclusively refer to the NV-center.

### The NV Excited State

The electronic excited state of the NV center involves the promotion of an electron from the |a₁ [symbol] orbital to either the |eₓ [symbol] or |e_{y} [symbol] orbitals (FIG. 12C). Here too, we can use the same procedure to construct the singlet and the triplet excited states. In particular, the triplet excited state manifold (³E) comprises six states which are linear combinations of the following orbital, and spin degrees of freedom [23]:

$$\{ \begin{matrix}( \vert {a}_{1} {e}_{x} 〉 - \vert {e}_{x} {a}_{1} 〉 ) \\ ( \vert {a}_{1} {e}_{y} 〉 - \vert {e}_{y} {a}_{1} 〉 )\end{matrix} \} ⊗ \vert S = 1 , {m}_{s} 〉$$

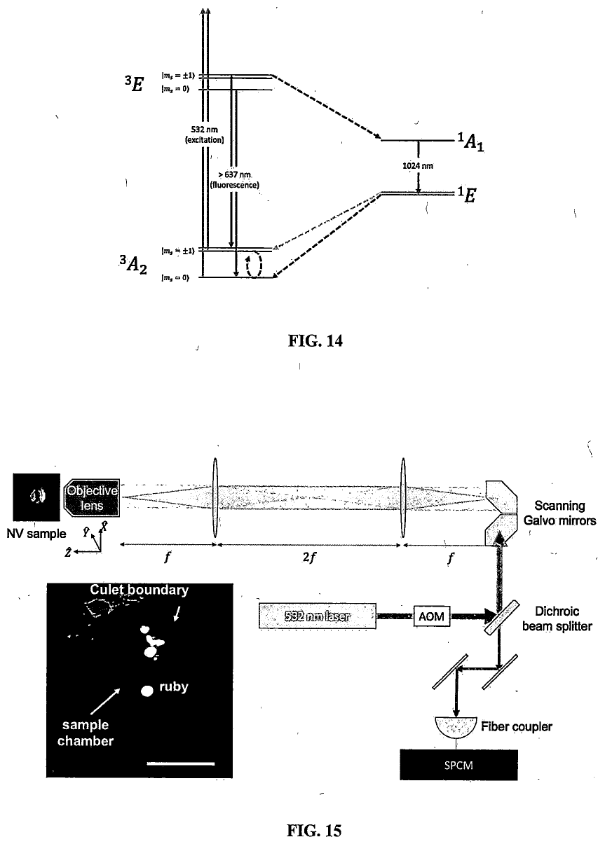

The relaxation between the ³E manifold and the ³A₂ ground state is responsible for the NV center's fluorescence (FIG. 14). At room temperature, all the optical lines between the ground state and the excited state are broadened into a single zero phonon line (ZPL) at 637 nm. However, a majority of the photoluminescent emission of the NV center is contained in a broad phonon sideband (PSB) extending up to ˜900 nm. The relaxation from the ³E excited state to the phononic excitations of the ³A₂ ground state contributes to this sideband emission [29].

### Dynamics of the NV Center

This section covers the photophysics of NV fluorescence, building on our understanding of the NV level structure (FIG. 14). In practice, we ‘talk’ to the NV center by exciting the optical transition from ³A₂→³E and collecting the fluorescent photons emitted by the NV center as the electron relaxes back to the ground state. Green light at 532 nm is optimal for excitation because it also stabilizes the NV-charge state over the NV⁰ charge state. The fluorescent transition back to the ground state is spin conserving, implying that repeated cycles of excitation and relaxation will not alter the spin state populations of the NV center.

In addition to this fluorescent (radiative) relaxation, electrons with |mₛ=±1 [symbol] states of the ³E manifold can transition into ¹A₁ singlet state. This non-radiative transition (which roughly occurs for ˜30% of the excitation cycles in the |mₛ=±1 [symbol] spin states) is mediated by spin-orbit coupling [45]. Within the singlet manifold, there is an additional fluorescent line at 1024 nm from the ¹A₁→¹E state, which is filtered out in our experiments. The electrons can transition from the ¹E state back into the ³A₂ ground state through an additional non-radiative decay channel. The branching ratio for this transition marginally favors the electronic relaxation into the |mₛ=0 [symbol] spin state in the ground state manifold (as shown by the darker arrow in FIG. 14) [29, 45]. This overall relaxation from the ³E state to the ³A₂ ground state via the singlet manifold is called the intersystem crossing (ISC).

FIG. 14 illustrates the NV ISC mechanism: Electrons in the ground ³A₂ state are o←^{I}-resonantly excited using a 532 nm beam to the ³E excited state. The excited state has a lifetime of ˜10 ns at cryogenic temperature, and the electrons can fluoresce back into a ground state, releasing a red photon (637-900 nm). For the |³E, mₛ=±1 [symbol] states, complementary to this radiative spin conserving process, the electron can non-radiatively transition into the ¹A₁ state in the singlet manifold. An additional fluorescence line at 1024 nm in the singlet manifold is filtered out in the experiments. The branching ratio of the second nonradiative relaxation path from the single ¹E states back to the ground state marginally favors, the electronic population in the (³A₂ mₛ=0 [symbol] state. The microscopic mechanism for this process is believed to be due to a stimulated phonon emission process [100]. This intersystem crossing mechanism, occurring over a timescale of ˜300 ns, is crucial for optical pumping and spin state readout of the NV center. In addition to optical transitions, the NV center also shows ground-state spin coherence. Using MW radiation, we can induce coherent oscillations among the |³A₂,mₛ [symbol] spin states (blue dashed arrow)—a mainstay of the NV center's room temperature quantum applications. 1

The ISC mechanism plays a central role in the NV center use in quantum technologies due to the following:
Optical pumping to |mₛ=0 [symbol] : The upper branch of the ISC (³E→¹ A₁) is spin selective [45]. In comparison, the transition rates from the ¹E singlet to the ³A₂ spin states are comparable [100]. It is easy to imagine that over multiple cycles of excitation, electrons in the |³A₂, mₛ=±1 [symbol] states will progressively get pumped into the |³A₂, mₛ==0 [symbol] state. Therefore, the ISC mechanism is key to state preparation of the NV center.
Spin state readout: The lifetime of the ³E excited state is ˜10 ns whereas that of the ¹E singlet state is ˜370 ns at cryogenic temperatures [100]. Given that relaxation through the ISC path is non-radiative (non-fluorescent), one can infer that the |³A₂,mₛ=0 [symbol] will be brighter than the |³A₂, mₛ=±1 [symbol] states. In experiments, measuring the fluorescence contrast (relative difference in fluorescence) enables us to perform spin state readout of the NV center.

### Electron Spin Resonance

Coherent control of the NV center's ground state spin at room temperature is a key advantage in its use in quantum technologies. The depolarization time (T₁) of the NV center is on the order of milliseconds (˜1 ms) [54]; and the decoherence time (T₂) can be pushed to ˜100 us using clever dynamical decoupling techniques [22]. Essentially, this means that within the ground electronic ³A₂ state, one can use microwave (MW) radiation to induce transitions between the |S=1, mₛ [symbol] sublevels unlocking the capability of performing a plethora of NMR-type measurements with the NV's electronic spin.

### How to Set Up a Confocal NV Experiment

Equipped with an understanding of the NV center and its amazing properties, our task then is to build an apparatus that is capable of making measurements. At a minimum, we need to be able to:
Excite the NV center from the ³A₂→³E state for optical pumping
Collect and measure the fluorescence from the NV center
Apply microwaves (MW) at ˜3 GHz for spin state manipulation

In practice, the most common design for an NV experimental setup is a scanning confocal fluorescence microscope integrated with MW control. The optics is reasonably straightforward, and a seasoned experimentalist can easily build an NV experiment in a couple of days (if not a few hours). A schematic for the experiment is shown in FIG. 1.5 with the setup details included in the figure caption.

FIG. 15 is a schematic illustration of a confocal NV fluorescence microscope: The beam of a 532 nm laser (Coherent Compass 315M or Coherent Verdi V-2), switched by a double pass AOM (Gooch & Housego AOMO 3110-120) setup, is directed towards a pair of scanning galvo mirrors (Thorlabs GVS212) using a dichroic beamsplitter (Semrock FF552-Di02). Following the galvo, a 4f telescope comprising two converging lenses is used to focus the excitation beam (green) onto the rear window of a high NA objective lens (typically a Mitutoyo M Plan APO long working distance objective). The voltage-controlled galvo mirrors raster the excitation beam in XY while the 4f system fixes the focus of the beam at the objective entrance enabling one to scan the excitation laser over the sample region. Scanning in the Z axis is enabled by a piezo objective mount (Edmond Optics nanopositioning piezo actuator) with 100 μm range. The NV fluorescence (red beam) at the sample captured over some solid angle by the objective counter propagates along the excitation path. The dichroic beam splitter transmits the fluorescence beam, and additional filters are used to chop out parasitic excitation photons and NV⁰ fluorescence. The fluorescence beam is then coupled to a fiber (the fiber core acts as the pinhole in our confocal setup). In all experiments, a single photon counter (Excelitas SPCM-AQRH-64-FC) was used to measure the fluorescence signal. (bottom left) A sample NV fluorescence scan of a pressure loading is shown. One can clearly see the culet and facets of the diamond anvil as well as the sample chamber and ruby pressure marker. White scale bar shows 100 μm.

In this section, most of the data taking was shared between two confocal setups (the first at room temperature and the second integrated with an Attocube attoDRY 800 cryostat). Additionally, for some experiments, we took data on a room temperature widefield setup.

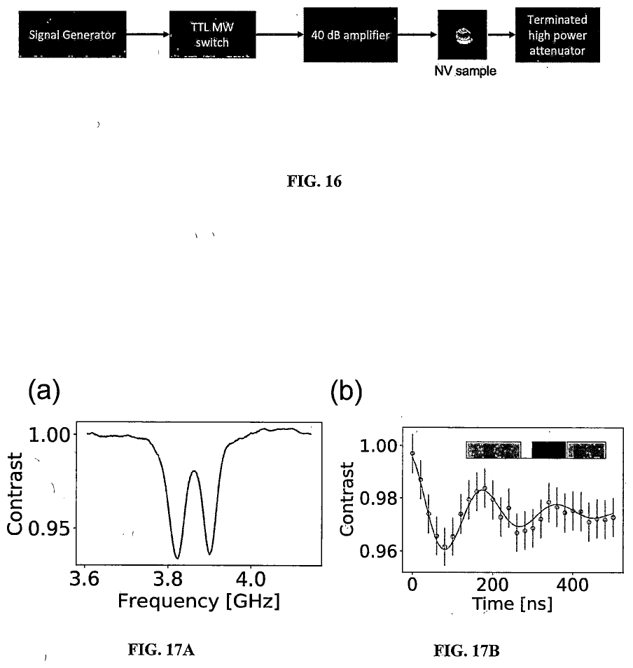

To integrate MW control into our confocal setup, we used a stripline or wire near the NV sample as a MW antenna. We performed spin state manipulation by channeling high-power microwaves through the antenna. FIG. 16 shows a schematic of the MW circuit used in our experiments. In particular, a microwave signal generator (SRS SG386 or SG384) is used for both pulsed and continuous wave experiments. A MW switch (Minicircuits ZASWA-2-50DR) is used to shutter any spurious leakage in the MW channel. A high-power class A amplifier (Minicircuits ZHL-15W-422-S+) is used to amplify the MW prior to channeling the radiation to the NV sample. Downstream from the sample, a 50 [symbol] terminated high power attenuator (Minicircuits BW-N40W50+) is used to absorb the MW signal to prevent any reflection back to the sample.

### Measurements Using the NV Center

In this section, two main measurement schemes are employed in NV (and other NMR-like) systems. This will give a sense of what the measurement protocol entails and how the measurement signal is obtained. Detailed descriptions of measurement sensitivity can be found in [9].

### Continuous Wave Experiments

The majority of the experiments in this section are continuous wave optically detected magnetic resonance (cwODMR) measurements. ODMR implies that magnetic dipole transitions in the ground state spin manifold are detected optically using a fluorescence contrast measurement. During a cwODMR measurement, the excitation laser is always ON. Under this condition, one can model the optical pumping process as a competition between the fluorescent relaxation and ISC transitions, yielding a steady state population of ground state spins. The majority of the NV spin populations will be in the |m_s=0 [symbol] state. We now apply microwaves and tune the MW frequency across the ground state zero-field splitting. On resonance, the MW will induce a transition from |m_s=0 [symbol] [symbol] |m_s=±1 [symbol] . This will offset the steady-state populations and reduce the overall fluorescence of the NV center. In FIG. 17A, a cwODMR signal at 120 GPa shows two such resonance peaks stemming from transitions from the |m_s=0 [symbol] state to eigenstates in the |m_s=±1 [symbol] manifold under stress. Therefore, by measuring the fluorescence synchronously with a change in the MW frequency, we can optically detect the NV electrons' magnetic resonance signal.

### Pulsed Experiments

The cwODMR measurement described above is an incoherent process. In contrast, pulsed measurements leverage the coherence of the spin levels. Instead of trying to explicate the expansive arsenal of pulsed measurements available to us, I will only describe a simple Rabi measurement to provide an idea of how pulsed measurements work in practice. Very broadly, it can be broken down into three steps:
State preparation: This step generally involves ˜100 us long laser pulse to prepare the NV in the |mₛ=0 [symbol] state. If required, a calibrated MW pulse can subsequently be used to prepare the system in any of the spin states or a coherent superposition thereof. A wait time is generally included to control for any charge dynamics in the system following the long laser pulse as well as for electrons in the singlet state to relax back into the ground state manifold.
MW pulse sequence: A sequence of choice can be applied to the NV center to direct the time evolution of the spin states, decouple environmental noise, etc. In reality, this sequence can be as simple as a MW pulse with a fixed frequency applied for a varying duration (in the case of the Rabi measurement) or a complicated sequence of pulses for simulation or sensing [9].
Readout: In the final step, we measure the fluorescence of spin state as an indicator of the population in different spin sublevels. A readout pulse is generally calibrated to be about ˜1 μs.
Readout Reference: A second reference pulse is taken after the readout pulse to correct for fluctuations in laser power and other experimental factors (such as drift in the optical alignment). The reference pulse provides an estimate of the background fluorescence when the NV spin is in the |mₛ=0 [symbol] state. The ratio of the raw readout counts and the reference counts yields a better estimate of the final state populations in practice.

In the Rabi experiment, starting in the |mₛ=0 [symbol] state, a resonant MW pulse can cycle the spin between |mₛ=0 [symbol] [symbol] |mₛ=±1 [symbol] states. We can directly see this when we plot the normalized readout counts against the length of the MW pulse. The strength of the magnetic dipole coupling of the NV center to the applied MW pulses defines the frequency of this oscillation (called the Rabi frequency). The decaying envelope of the Rabi signal defines the dephasing T₂*timescale.

FIG. 17A-17B provide NV measurements at ˜120 GPa: (a) A room temperature cwODMR spectrum at high pressure showing the resonances between the ground state |mₛ=0 [symbol] and |mₛ=±1 [symbol] states. The |mₛ=±1 [symbol] states are shifted, split, and mixed due to crystal stress. (b) A low-temperature Rabi measurement at the same pressure: The pulse sequence for a Rabi experiment (inset) starts with a polarization pulse to prepare the NV center in the |mₛ=0 [symbol] state. Following a short wait time, a MW pulse at the resonance frequency is ap-plied for a variable time. A state readout pulse shows rabi oscillations as a function of the length of the MW pulse. A second reference readout pulse (not shown) can control for drift in NV counts over the course of the data taking.

Single NV Vs. Ensemble Measurements

A second distinction must be made regarding the types of NV measurements. On the one hand, experiments can use a sample rich in NV centers that measure more than ˜1000 NVs in one diffraction spot [49]. Alternatively, one can use a sparse sample where experiments measure the behavior of individual NV centers. The former is an ensemble measurement, whereas the latter is a single NV measurement. Each type of measurement has its tradeoffs pertaining to SNR, sensitivity, and integration time. The right choice will necessarily depend on the goals of the project. In this thesis, all high-pressure experiments are ensemble experiments.

### NV Sensing: Vector Magnetometry

This section shows how the tools introduced so far can work in concert to make meaningful measurements. Barry et al. [9] give a thorough review of NV sensing protocols from the standpoint of sensitivity improvement. Here, I will only provide a simple illustration of vector magnetometry to show the concept and usefulness of NV sensing at a high level. In particular, I hope to impress upon the reader that one can leverage ensemble NV sensing to reconstruct vectorial and tensorial information of the parameter of interest. I have often found myself using this technique in the lab.

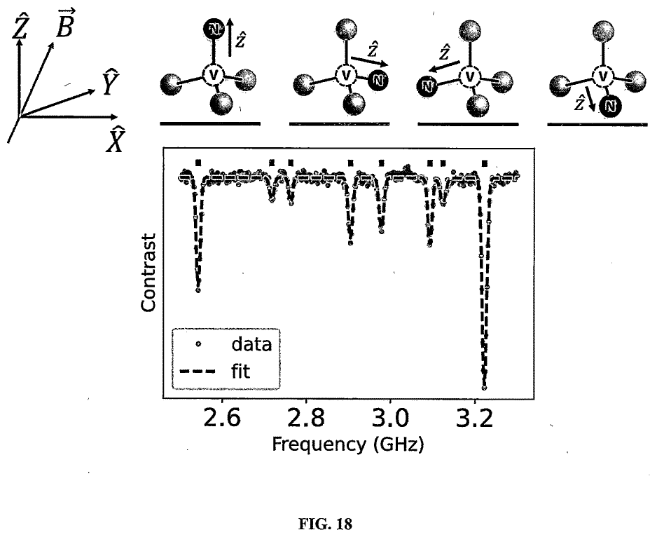

FIG. 18 provides an example of vector magnetometry: There are four groups of NV centers in diamond with the N-V axis oriented along each of the four diamond bonds. The ground state spin of each group is quantized along its respective NV axes (\hat{ }z). In this figure, the four groups are depicted in terms of their crystal orientation (top). The application of a generic B˜ field (shown in the crystal frame on the top left) will result in eight resonance lines (two for each NV group) in a cwODMR spectrum. This is because the magnitude of the field projection in the frame of each NV group will determine the shift and splitting of these lines. In the ODMR spectrum, the lines from each group are paired and denoted by the color associated with each group. The four groups are ordered according to the magnitude of the field projection in their respective frames.

In practice, the quantization axis (\hat{ }z) of an NV center can be oriented along any of the four bonds in the diamond crystal. Pictorially, this translates to the nitrogen-vacancy axis lying along this bond (FIG. 18). Therefore, there are four different NV groups in a diamond sample with tetrahedrally oriented quantization axes. In the presence of a generic magnetic field, the NV groups couple to the projection of the B˜ field in its reference frame, yielding the following Hamiltonian for the system:

$$H = {\sum }_{i = 1 , 2 , 3 , 4} {D}_{gs} {S}_{z , i}^{2} + γ {\vec{B}}^{( i )} \cdot {\vec{S}}_{i} \qquad ( 1.6 )$$

where D_{gs}=(2π)×2.87 GHz is the zero field splitting, ˜(2π)×2.8 MHz/G is the gyromagnetic ratio, and {S_{x,i},S_{y,i},S_{z,i}} are the spin-1 matrices for the i-th NV group. Intuitively, the field projection along \hat{ }z⁽ⁱ⁾ couples linearly, causing a Zeeman splitting of 2 γ

$${B}_{z}^{( i )}$$

between the |m_s=±1 [symbol] spin states. In contrast, the off-axis components

$$( {B}_{x}^{( i )} , {B}_{y}^{( i )} )$$

are suppressed by the zero-field splitting term and perturbatively couple at second order (at low fields). These off-axis fields result in a shift and a splitting of the order˜

$${( γ {B}_{x , y}^{( i )} )}^{2} / {D}_{gs} .$$

Therefore, the application of a non-degenerate B˜ field will yield eight resonances in the ODMR spectrum (two from each of the NV groups as in FIG. 18). For each group, it is possible to fit

$${B}_{z}^{( i )} and {B}_{⊥}^{( i )} = \sqrt{{B}_{x}^{( i ) 2} + {B}_{y}^{( i ) 2}}$$

from the shift and the splitting values. Reconstructing the three free parameters of (B_{X}, B_{Y}, B_{Z}) in the lab frame from these eight resonances can then be relegated to an optimization routine.

Note: As mentioned earlier, upper case (X\hat{ },Y\hat{ },Z\hat{ }) is for the lab reference frame and lower case (x\hat{ },y\hat{ },z\hat{ }) to denote the reference frame of a single NV group. Except for special cases, the two frames are not coincident.

Note that we can think of the NV center as a spin 1 defect in diamond, with three quantum states that can be reliably initialized, coherently controlled and measured.

### BIBLIOGRAPHY

[1]V. M. Acosta et al. “Temperature Dependence of the Nitrogen-Vacancy Magnetic Resonance in Diamond”. In: Phys. Rev. Lett. 104 (7 Feb. 2010), p. 070801. doi: 10.1103/PhysRevLett.104. 070801. url: https://link.aps.org/doi/10.1103/PhysRevLett.104.0708012.
[2] Yuichi Akahama and Haruki Kawamura. “Pressure calibration of diamond anvil Raman gauge to 310 GPa”. In: Journal of Applied Physics 100.4 (2006), p. 043516.
[3] Yuichi Akahama and Haruki Kawamura. “Raman study on the stress state of [111] diamond anvils at multimegabar pressure”. In: Journal of applied physics 98.8 (2005), p. 083523.
[4]T P Alegre et al. “Polarization-selective excitation of N V centers in diamond”. In: arXii preprint arXiv:0705.2006 (2007).
[5]D J Andrews. “Equation of state of the alpha and epsilon phases of iron”. In: Journal of Physics and Chemistry of Solids 34.5 (1973), pp. 825-840.
[6]N. W. Ashcroft. “Metallic Hydrogen: A High-Temperature Superconductor?” In: Phys. Rev. Lett. 21 (26 Dec. 1968), pp. 1748-1749. doi: 10.1103/PhysRevLett. 21.1748. url: https://lin,k.aps.org/doi/10.1103/PhysRevLett.21.1748.
[7] Nabeel Aslam et al. “Photo-induced ionization dynamics of the nitrogen vacancy defect in diamond investigated by single-shot charge state detection”. In: New Journal of Physics 15.1 (2013), p. 013064.
[8]A-L Auzende et al. “High-pressure behaviour of serpentine minerals: a Raman spectroscopic study”. In: Physics and Chemistry of Minerals 31.5 (2004), pp. 269-277.
[9] John F. Barry et al. “Sensitivity optimization for N V-diamond magnetometry”. In: Rev. Mod. Phys. 92 (1 Mar. 2020), p. 015004. doi: 10.1103/RevModPhys.92.015004. url: https://link.aps.org/doi/10.1103/RevModPhys.92.015004.
[10] Michael S J Barson et al. “Nanomechanical sensing using spins in diamond”. In: Nano letters 17.3 (2017), pp. 1496-1503.
[11] William A Bassett. “Deviatoric stress: a nuisance or a gold mine?” In: Journal of Physics: Condensed Matter 18.25 (2006), S921.
[12] William A. Bassett. “Diamond anvil cell, 50th birthday”. In: High Pressure Research 29.2 (2009), pp. 163-186. doi: 10.1080/08957950802597239. eprint: https://doi.org/10.1080/08957950802597239. url: https://doi.org/10.1080/08957950802597239.
[13] J Georg Bednorz and K Alex Mu\ddot{ } ller. “Perovskite-Type Oxides—the New Approach to High-Tc Superconductivity. Nobel Lecture”. In: Angewandte Chemie International Edition in English 27.5 (1988), pp. 735-748.
[14] R Berman, Franz Eugen Simon, and John Michael Ziman. “The thermal conductivity of diamond at low temperatures”. In: Proceedings of the Royal Society of London. Series A. Mathematical and Physical Sciences 220.1141 (1953), pp. 171-183.
[15] Magali I Billen. “Deep slab seismicity limited by rate of deformation in the transition zone”. In: Science advances 6.22 (2020), eaaz7692.
[16]M Block et al. “Optically enhanced electric field sensing using nitrogen-vacancy ensembles”. In: Physical Review Applied 16.2 (2021), p. 024024.
[17]E Bourgeois et al. “Photoelectric detection of electron spin resonance of nitrogenvacancy centres in diamond”. In: Nature. Communications 6.1 (Oct. 2015), p. 8577.
[18] Shubhayu Chatterjee, Joaquin F Rodriguez-Nieva, and Eugene Demler. “Diagnosing phases of magnetic insulators via noise magnetometry with spin qubits”. In: Physical Review B 99.10 (2019), p. 104425.
[19] Yu-Chen Chen et al. “Laser writing of coherent colour centres in diamond”. In: Nature Photonics 11.2 (2017), pp. 77-80.
[20] Edward H. Chen et al. “High-sensitivity spin-based electrometry with an ensemble of nitrogen-vacancy centers in diamond”. In: Phys. Rev. A 95 (5 May 2017), p. 053417. doi: 10.1103/PhysRevA.95.053417. url: https://link.aps.org/doi/10.1103/PhysRevA.95.053417.
[21] Wuhao Chen et al. “High-Temperature Superconducting Phases in Cerium Superhydride with a T c up to 115 K below a Pressure of 1 Megabar”. In: Physical Review Letters 127.11 (2021), p. 117001.
[22] Lilian Isabel Childress. Coherent manipulation of single quantum systems in the solid state. Harvard University, 2007.
[23] Yiwen Chu and Mikhail D Lukin. “Quantum optics with nitrogen-vacancy centers in diamond”. In: Quantum Optics and Nanophotonics (2015), pp. 229-270.
[24] Wikimedia Commons. Expulsion of magnetic field lines upon entering the superconducting phase. Piotr Jaworski; ; Poznan′/POLAND. 2005. url: https://commons.wikimedia.org/wiki/File:EXPULSION.png.
[25] Jian-Hong Dai et al. “Optically Detected Magnetic Resonance of Diamond N V Centers under Megabar Pressures”. In: Chinese Physics Letters (2022). url: http://iopscience.iop.org/article/10.1088/0256-307X/39/11/117601.
[26] Gordon Davies and M F Hamer. “Optical studies of the 1.945 eV vibronic band in diamond”. In: Proceedings of the Royal Society of London. A. Mathematical and Physical Sciences 348.1653 (1976), pp. 285-298.
[27] Agn′es Dewaele and Lucie Nataf. “Magnetic phase diagram of iron at high pressure and temperature”. In: Phys. Rev. B 106 (1 Jul. 2022), p. 014104. doi: 10.1103/PhysRevB.106.014104. urk: https://link.aps.org/doi/10.1103/PhysRevB.106.014104.
[28] Marcus W. Doherty et al. “Electronic Properties and Metrology Applications of the Diamond N V Center under Pressure”. In: Phys. Rev. Lett. 112 (4 Jan. 2014), p. 047601. doi: 10.1103/PhysRevLett.112.047601. url: https://link.aps.org/doi/10.1103/PhysRevLett.112.047601.
[29] Marcus W. Doherty et al. “The nitrogen-vacancy colour centre in diamond”. In: Physics Reports 528.1 (2013). The nitrogen-vacancy colour centre in diamond, pp. 1-45. issn: 0370-1573. doi: https://doi.org/10.1016/j.physrep.2013.02.001. url: https://www.sciencedirect.com/science/article/pii/S03701573130 00562.
[30] Florian Dolde et al. “Electric-field sensing using single diamond spins”. In: Nature Physics 7.6 (2011), pp. 459-463.
[31] Pavel E Dolgirev et al. “Characterizing two-dimensional superconductivity via nanoscale noise magnetometry with single-spin qubits”. In: Physical Review B 105.2 (2022), p. 024507.
[32] A. P. Drozdov et al. “Conventional superconductivity at 203 kelvin at high pressures in the sulfur hydride system”. In: Nature 525.7567 (Sept. 2015), pp. 73-76. issn: 14764687. doi: 10.1038/naturel4964. url: https://doi.org/10.1038/naturel4964.
[33] A. P. Drozdov et al. “Superconductivity at 250 K in lanthanum hydride under high pressures”. In: Nature 569.7757 (May 2019), pp. 528-531. issn: 1476-4687. doi: 10. 1038/s41586-019-1201-8. url: https://doi.org/10.1038/s41586-019-1201-8.
[34] A P Drozdov et al. “Conventional superconductivity at 203 kelvin at high pressures in the sulfur hydride system”. In: Nature 525.7567 (2015), pp. 73-76.
[35] Natalia Dubrovinskaia and Leonid Dubrovinsky. “Whole-cell heater for the diamond anvil cell”. In: Review of Scientific Instruments 74.7 (2003), pp. 3433-3437.
[36] M. I. Eremets. High Pressure Experimental Methods. Oxford science publications. Oxford University Press, 1996. isbn: 9780198562696. url: https://books.google.com/books?id=3bD0mTRON8C.
[37] Jacopo Forneris et al. “Mapping the Local Spatial Charge in Defective Diamond by Means of N-V Sensors-A Self-Diagnostic Concept”. In: Physical Review Applied 10.1 (2018), p. 014024.
[38]C Frohlich. “The Nature of Deep-Focus Earthquakes”. In: Annual Review of Earth and Planetary Sciences 17.1 (1989), pp. 227-254. doi: 10.1146/annurev.ea.17.050189. 001303. eprint: https://doi.org/10.1146/annurev.ea.17.050189.001303. url: https://doi.orq/10.1146/annurev.ea.17.050189.001303.
[39] Cli [symbol] Frohlich. Deep Earthquakes. Cambridge University Press, 2006. doi: 10.1017/CB09781107297562.
[40]G D Fuchs et al. “Excited-state spectroscopy using single spin manipulation in diamond”. In: Physical review letters 101.11 (2008), p. 117601.
[41] A G Gavriliuk, A A Mironovich, and V V Struzhkin. “Miniature diamond anvil cell for broad range of high pressure measurements”. In: Review of Scientific Instruments 80.4 (2009), p. 043906.
[42]B K Godwal et al. “High pressure equation of state studies using methanol-ethanol-water and argon as pressure media”. In: Journal of Physics and Chemistry of Solids 71.8 (2010), pp. 1059-1064.
[43] Narayama Golding et al. “Plastic faulting in ice”. In: Journal of Geophysical Research: Solid Earth 125.5 (2020), e2019JB018749.
[44] Michael Lurie Goldman et al. “Phonon-induced population dynamics and intersystem crossing in nitrogen-vacancy centers”. In: Physical review letters 114.14 (2015), p. 145502.
[45] Michael Lurie Goldman et al. “State-selective intersystem crossing in nitrogen-vacancy centers”. In: Physical Review B 91.16 (2015), p. 165201.
[46] Sara Haravifard et al. “Continuous and discontinuous quantum phase transitions in a model two-dimensional magnet”. In: Proceedings of the National Academy of Sciences 109.7 (2012), pp. 2286-2289.
[47]J E Hirsch and F Marsiglio. “Evidence against superconductivity in flux trapping experiments on hydrides under high pressure”. In: Journal of Superconductivity and Novel Magnetism 35.11 (2022), pp. 3141-3145.
[48] Kin On Ho et al. “Recent developments of quantum sensing under pressurized environment using the nitrogen vacancy (N V) center in diamond”. In: Journal of Applied Physics 129.24 (2021), p. 241101.
[49]S Hsieh et al. “Imaging stress and magnetism at high pressures using a nanoscale quantum sensor”. In: Science 366.6471 (2019), pp. 1349-1354.
[50] Xiaoli Huang et al. “High-temperature superconductivity in sulfur hydride evidenced by alternating-current magnetic susceptibility”. In: National Science Review 6.4 (2019), pp. 713-718.
[51] Ryuji Igarashi et al. “Real-Time Background-Free Selective Imaging of Fluorescent Nanodiamonds in Vivo”. In: Nano Letters 12.11 (Nov. 2012), pp. 5726-5732.
[52] Kay D Jahnke et al. “Electron-phonon processes of the silicon-vacancy centre in diamond”. In: New Journal of Physics 17.4 (2015), p. 043011.
[53] P. Jamonneau et al. “Competition between electric field and magnetic field noise in the decoherence of a single spin in diamond”. In: Phys. Rev. B 93 (2 Jan. 2016), p. 024305. doi: 10.1103/PhysRevB.93.024305. url: https://link.aps.org/doi/10.1103/PhysRevB.93.024305.
[54] A Jarmola et al. “Temperature-and magnetic-field-dependent longitudinal spin relaxation in nitrogen-vacancy ensembles in diamond”. In: Physical review letters 108.19 (2012), p. 197601.
[55] A Jayaraman. “High pressure studies: Metals, alloys and compounds”. In: Handbook on the Physics and Chemistry of Rare Earths 1 (1978), pp. 707-747.
[56] Innokenty Kantor et al. “BX90: A new diamond anvil cell design for X-ray di [symbol] raction and optical measurements”. In: Review of Scientific Instruments 83.12 (2012), p. 125102.
[57] Kathleen J Kingma et al. “High-pressure crystalline transformations and amorphization in [symbol] -quartz”. In: AIP Conference Proceedings. Vol. 309. American Institute of Physics. 1994, pp. 39-42.
[58] M B Kruger and Raymond Jeanloz. “Memory glass: an amorphous material formed from AlPO4”. In: Science 249.4969 (1990), pp. 647-649.
[59] Y Kubo et al. “Strong Coupling of a Spin Ensemble to a Superconducting Resonator”. In: Physical Review Letters 105.14 (Sept. 2010), p. 140502.
[60] Ngoc Diep Lai et al. “Influence of a static magnetic field, on the photoluminescence of an ensemble of nitrogen-vacancy color centers in a diamond single-crystal”. In: Applied Physics Letters 95.13 (2009), p. 133101. doi: 10.1063/1.3238467. eprint: https: //doi.org/10.1063/1.3238467. url: https://doi.org/10.1063/1.3238467.
[61] Margarita Lesik et al. “Magnetic measurements on micrometer-sized samples under high pressure using designed N V centers”. In: Science 366.6471 (2019), pp. 1359-1362.
[62] A. O. Levchenko et al. “Inhomogeneous broadening of optically detected magnetic resonance of the ensembles of nitrogen-vacancy centers in diamond by interstitial carbon atoms”. In: Applied Physics Letters 106.10 (2015), p. 102402. doi: 10.1063/1.4913428. eprint: https://doi.org/10.1063/1.4913428. url: https://doi. org/10.1063/1.4913428.
[63] Valery I Levitas. “High-pressure phase transformations under severe plastic deformation by torsion in rotational anvils”. In: Materials Transactions 60.7 (2019), pp. 1294-1301.
[64] Valery I Levitas et al. “High-density amorphous phase of silicon carbide obtained under large plastic shear and high pressure”. In: Physical Review B 85.5 (2012), p. 054114.
[65] Bing Li et al. “Diamond anvil cell behavior up to 4 Mbar”. In: Proceedings of the National Academy of Sciences 115.8 (2018), pp. 1713-1717.
[66] D R Lide. Handbook of Chemistry and Physics, 86th edn. CRC. 2005.
[67] Shengran Lin et al. “Temperature-dependent coherence properties of N V ensemble in diamond up to 600 K”. In: Physical Review B 104.15 (2021), p. 155430.
[68] Gang-Qin Liu et al. “Coherent quantum control of nitrogen-vacancy center spins near 1000 kelvin”. In: Nature communications 10.1 (2019), pp. 1-8.
[69] S. G. Lyapin et al. “Study of optical properties of the N V and SiV centres in diamond at high pressures”. English. In: Nanosystems: Physics, Chemistry, Mathematics 9.1 (2018). Copyright—Copyright St. Petersburg National Research University of Information Technologies, Mechanics and Optics 2018; Last updated—2018-03-21, pp. 55-57. url:https://www.proquest.com/scholarly-journals/study-opticalproperties-nv-siv-centres-diamond/docview/2015777350/se-2.
[70] Ho-Kwang Mao et al. “Solids, liquids, and gases under high pressure”. In: Rev. Mod. Phys. 90 (1 Mar. 2018), p. 015007. doi: 10. 1103/RevModPhys.90.015007. url: https://link.aps.org/doi/10.1103/RevModPhys.90;015007.
[71] Teruo Matsushita et al. Flux pinning in superconductors. Vol. 164. Springer, 2007.
[72] Y Matsuzaki et al. “Optically detected magnetic resonance of high-density ensemble of N V centers in diamond”. In: Journal of Physics: Condensed Matter 28.27 (July 2016), p. 275302.
[73] Jeronimo R Maze et al. “Properties of nitrogen-vacancy centers in diamond: the group theoretic approach”. In: New Journal of Physics 13.2 (2011), p. 025025.
[74] Charles Meade and Raymond Jeanloz. “Deep-focus earthquakes and recycling of water into the Earth's mantle”. In: Science 252.5002 (1991), pp. 68-72.
[75] Thomas Mittiga et al. “Imaging the local charge environment of nitrogen-vacancy centers in diamond”. In: Physical review letters 121.24 (2018), p. 246402.
[76] Robert M Nadeau and Lane R Johnson. “Seismological studies at Parkfield V I: Moment release rates and estimates of source parameters for small repeating earthquakes”. In: Bulletin of the Seismological Society of America 88.3 (1998), pp. 790-814.
[77] N M Nusran et al. “Spatially-resolved study of the Meissner e [symbol] ect in superconductors using N V-centers-in-diamond optical magnetometry”. In: New Journal of Physics 20.4 (2018), p. 043010.
[78] Earl F O'Bannon III et al. “Contributed Review: Culet diameter and the achievable pressure of a diamond anvil cell: Implications for the upper pressure limit of a diamond anvil cell”. In: Review of Scientific Instruments 89.11 (2018), p. 111501.
[79] Eric Van Oort and Max Glasbeek. “Electric-field-induced modulation of spin echoes of N-V centers in diamond”. In: Chemical Physics Letters 168.6 (1990), pp. 529-532. issn: 0009-2614. doi: https://doi.org/10.1016/0009-2614 (90) 85665-Y. url: http://www.sciencedirect.com/science/article/pii/000926149085 665Y.
[80] La′szl′o Oroszla′ny et al. “Magnetism of gadolinium: a first-principles perspective”. In: Physical review letters 115.9 (2015), p. 096402.
[81] Chris J Pickard, Ion Errea, and Mikhail I Eremets. “Superconducting hydrides under pressure”. In: Annual Review of Condensed Matter Physics 11 (2020), pp. 57-76.
[82] Hugh O Pierson. Handbook of carbon, graphite, diamonds and fullerenes: processing, properties and applications. William Andrew, 2012.
[83] Bruno Reynard et al. “Elasticity of serpentines and extensive serpentinization in subduction zones”. In: Geophysical Research Letters 34.13 (2007).
[84] Lawrence Baylor Robinson, Frederick Milstein, and A Jayaraman. “E [symbol] ect of pressure on the Curie temperature of rare-earth metals. I. Gadolinium”. In: Physical Review 134.1A (1964), A187.
[85]L J Rogers et al., “Time-averaging within the excited state of the nitrogen-vacancy centre in diamond”. In: New Journal of Physics 11.6 (2009), p. 063007.
[86]L Rondin et al. “Magnetometry with nitrogen-vacancy defects in diamond”. In: Reports on Progress in Physics 77.5 (May 2014), p. 056503.
[87] Gopi K Samudrala et al. “Structural and magnetic phase transitions in gadolinium under high pressures and low temperatures”. In: High Pressure Research 34.4 (2014), pp. 385-391.
[88] Alexandre Schubnel et al. “Deep-focus earthquake analogs recorded at high pressure and temperature in the laboratory”. In: Science 341.6152 (2013), pp. 1377-1380.
[89] Dmitrii V Semenok et al. “On distribution of superconductivity in metal hydrides”. In: Current Opinion in Solid State and Materials Science 24.2 (2020), p. 100808.
[90] Yan-Xing Shang et al. “Magnetic Sensing inside a Diamond Anvil Cell via NitrogenVacancy Center Spins”. In: Chinese Physics Letters 36.8 (2019), p. 086201.
[91] Maria Simanovskaia et al. “Sidebands in optically detected magnetic resonance signals of nitrogen vacancy centers in diamond”. In: Phys. Rev. B 87 (22 Jun. 2013), p. 224106. doi: 10.1103/PhysRevB.87.224-106. url: https://link.aps.org/doi/10.1103/PhysRevB.87.224106.
[92] T Smart et al. “High-pressure nano-seismology: Use of micro-ring resonators for characterizing acoustic emissions”. In: Applied Physics Letters 115.8 (2019), p. 081904.
[93] Thomas James Smart. Structural Transitions in Materials at High Pressure. University of California, Berkeley, 2020.
[94] Benjamin Smeltzer, Lilian Childress, and Adam Gali. “13C hyperfine interactions in the nitrogen-vacancy centre in diamond”. In: New Journal of Physics 13.2 (2011), p. 025021.
[95] Maddury Somayazulu et al. “Evidence for Superconductivity above 260 K in Lanthanum Superhydride at Megabar Pressures”. In: Phys. Rev. Lett. 122 (2 Jan. 2019), p. 027001. doi: 10.1103/PhysRevLett.122.027001. url: https://link.aps.org/doi/10.1103/PhysRevLett.122.027001.
[96] L G Steele et al. “Optically detected magnetic resonance of nitrogen vacancies in a diamond anvil cell using designer diamond anvils”. In: Applied Physics Letters 111.22 (2017), p. 221903.
[97] Viktor Struzhkin et al. “Superconductivity in La and Y hydrides: Remaining questions to experiment and theory”. In: Matter and Radiation at Extremes 5.2 (2020), p. 028201.
[98] K Syassen. “Ruby under pressure”. In: High Pressure Research 28.2 (2008), pp. 75-126.
[99] R D Taylor, M P Pasternak, and R Jeanloz. “Hysteresis in the high pressure r transformation of bcc-to hcp-iron”. In: Journal of Applied Physics 69.8 (1991), pp. 6126-6128.
[100] Gergo” Thiering and Adam Gali. “Theory of the optical spin-polarization loop of the nitrogen-vacancy center in diamond”. In: Physical Review B 98.8 (2018), p. 085207.
[101] Michael Tinkham. Introduction to superconductivity. Courier Corporation, 2004.
[102] Ivan Troyan et al. “Observation of superconductivity in hydrogen sulfide from nuclear resonant scattering”. In: Science 351.6279 (2016), pp. 1303-1306.
[103] Pauli Virtanen et al. “SciPy 1.0: Fundamental Algorithms for Scientific Computing in Python”. In: Nature Methods 17 (2020), pp. 261-272. doi: 10.1038/s41592-0190686-2.
[104] Yogesh K. Vohra et al. “Band-Overlap Metallization of Cesium Iodide”. In: Phys. Rev. Lett. 55 (9 Aug. 1985), pp. 977-979. doi: 10.1103/PhysRevLett.55.977. url: https://link.aps.org/doi/10.1103/PhysRevLett.55.977.
[105] St′efan van der Walt et al. .scikit-image: image processing in Python”. In: PeerJ 2 (June 2014), e453. issn:2167-8359. doi: 10.7717/peerj.453. url: https://doi. org/10.7717/peerj.453.
[106] EJW Whittaker and Jack Zussman. “The characterization of serpentine minerals by X-ray di [symbol] raction”. In: Mineralogical magazine and journal of the Mineralogical Society 31.233 (1956), pp. 107-126.
[107] King Yau Yip et al. “Measuring magnetic field texture in correlated electron systems under extreme conditions”. In: Science 366.6471 (2019), pp. 1355-1359.
[108] Alexander M. Zaitsev. “Physical Classification of Diamond”. In: Optical Properties of Diamond: A Data Handbook. Berlin, Heidelberg: Springer Berlin Heidelberg, 2001, pp. 389-393. isbn: 978-3-662-04548-0. doi: 10. 1007/978-3-662-04548-0_7. url: https://doi.org/10.1007/978-3-662-04548-0_7.
[109] Xiaohua Zhang et al. “Pressure-induced hydride superconductors above 200 K”. In: Matter and Radiation at Extremes 6.6 (2021), p. 068201.
[110] Xin-Yue Zhang et al. “A C susceptometry of 2D van der Waals magnets enabled by the coherent control of quantum sensors”. In: PRX Quantum 2.3 (2021), p. 030352.
[111] Xiaobo Zhu et al. “Observation of dark states in a superconductor diamond quantum hybrid system”. In: Nature Communications 5 (Apr. 2014), p. 3424.
[112] James F. Ziegler, M. D. Ziegler, and J. P. Biersack. “SRIM—The stopping and range of ions in matter (2010)”. In: Nuclear Instruments and Methods in Physics Research Section B: Beam Interactions with Materials and Atoms 268.11 (2010). 19th International Conference on Ion Beam Analysis, pp. 181.8-1823. issn: 0168-583X. doi: https: //doi.org/10.1016/j.nimb.2010.02.091.url: https: //www.sciencedirect. com/science/article/pii/S0168583X10001862.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. A diamond anvil cell device, comprising:
a first diamond anvil having a culet cut to provide a first anvil surface that is substantially perpendicular to a [111] crystal axis thereof;
a second diamond anvil having a culet cut to provide a second anvil surface,
wherein at least one of said first and second diamond anvils comprises an ion-crystal-vacancy-defect pair formed therein at a distance of at least 10 nm to 5 μm from said corresponding first or second anvil surface, and
wherein a remaining portion of said at least one of said first and second diamond anvils at distances farther than 5 μm from said first or second anvil surface is substantially free of ion-crystal-vacancy-defect pairs.

2. The diamond anvil cell device according to claim 1, wherein said second diamond anvil has said culet cut to provide said second anvil surface so as to be substantially perpendicular to a [111] crystal axis thereof, and
wherein said first and second anvil surfaces oppose each other to form a pressure chamber therebetween.

3. The diamond anvil according to claim 1, further comprising a plurality of implanted ion-crystal-vacancy-defect pairs within said at least one of said first and second diamond anvils at distances of 10 nm to 5 μm from said corresponding first or second anvil surface at a density of 1 part per billion to 50 parts per million.

4. The diamond anvil cell device according to claim 3, wherein said density is 1 part per million to 10 parts per million.

5. The diamond anvil cell device according to claim 1, wherein said ion-crystal-vacancy-defect pair comprises an ion selected from the group consisting of germanium, nitrogen, silicon and tin.

6. The diamond anvil cell device according to claim 3, wherein each of said ion-crystal-vacancy-defect pairs comprises an ion selected from the group consisting of germanium, nitrogen, silicon and tin.

7. The diamond anvil cell device according to claim 1, wherein said ion-crystal-vacancy-defect pair comprises a nitrogen ion.

8. The diamond anvil cell device according to claim 3, wherein each of said ion-crystal-vacancy-defect pairs comprises a nitrogen ion.

9. The diamond anvil cell device according to claim 1, further comprising:
a first cell body attached to said first diamond anvil;
a second cell body attached to said second diamond anvil; and
a gasket defining a hole therethrough and arranged between said first and second diamond anvils so as to form said pressure chamber.

10. The diamond anvil cell device according to claim 9, wherein said first and second cell bodies are each formed from at least one of Beryllium copper, Steel, NiCrAl, and Tungsten Carbide, Pascalloy, Vascomax, Inconel, cubic boron nitride; and
wherein said gasket is formed from at least one of Rhenium, Berrylium copper, Steel, cubic boron nitride, Kapton, and Tungsten Carbide.

11. The diamond anvil cell device according to claim 1, further comprising a laser excitation system and a microwave excitation system.

12. The diamond anvil cell device according to claim 11, wherein said microwave excitation system comprises a platinum or gold antenna.

13. A diamond anvil for a diamond anvil cell, said diamond anvil being defined by a plurality of flat surfaces resulting from cuts in a bulk piece of diamond having [111], [100] and [110] crystal axes,
wherein one of said plurality of flat surfaces is a culet cut to provide an anvil surface of said diamond anvil,
wherein said culet is substantially perpendicular to said crystal axis of said bulk piece of diamond, and
wherein said diamond anvil comprises an ion-crystal-vacancy-defect pair formed therein at a distance of at least 10 nm to 5 μm from said anvil surface, and
wherein a remaining portion of said diamond anvil at distances farther than 5 μm from said anvil surface is substantially free of ion-crystal-vacancy-defect pairs.

14. The diamond anvil according to claim 13, further comprising a plurality of implanted ion-crystal-vacancy-defect pairs within said diamond anvil distances of 10 nm to 5 μm from said anvil surface at a density of 1 part per billion to 50 parts per million.

15. The diamond anvil according to claim 14, further comprising a plurality of implanted ion-crystal-vacancy-defect pairs within said diamond anvil distances of 10 nm to 5 μm from said anvil surface at a density of 1 part per million to 10 parts per million.

16. The diamond anvil according to claim 13, wherein said ion-crystal-vacancy-defect pair comprises an ion selected from the group consisting of germanium, nitrogen, silicon and tin.

17. The diamond anvil according to claim 14, wherein each of said ion-crystal-vacancy-defect pairs comprises an ion selected from the group consisting of germanium, nitrogen, silicon and tin.

18. The diamond anvil according to claim 13, wherein said ion-crystal-vacancy-defect pair comprises a nitrogen ion.

19. The diamond anvil according to claim 14, wherein each of said ion-crystal-vacancy-defect pairs comprises a nitrogen ion.

20. A method of producing a diamond anvil for a diamond anvil cell, comprising:
providing a piece of uncut diamond having [111], [100] and [110] crystal axes;
cutting said diamond to provide a plurality of flat surfaces, one of said plurality of flat surfaces being a culet cut to provide an anvil surface of said diamond anvil, wherein said culet is substantially perpendicular to said [111] crystal axis; and
implanting an ion in said diamond anvil to form an ion-crystal-vacancy-defect pair formed therein at a distance of at least 10 nm to 5 μm from said anvil surface,
wherein a remaining portion of said diamond anvil at distances farther than 5 μm from said anvil surface is substantially free of ion-crystal-vacancy-defect pairs.

21.-26. (canceled)
